(19) United States
(12) Patent Application Publication
(10) Pub. No.: US 2026/0037698 A1
(43) Pub. Date: Feb. 5, 2026

(54) IDENTIFYING RAW MATERIALS AND GAS PRODUCTION DATA

(71) Applicant: Fermentrics Technologies Inc., McNab/Braeside (CA)

(72) Inventors: James JOHNSTON, McNab/Braeside (CA); Robin JOHNSTON, Arnprior (CA); Meisam RAKHSHANFAR, Ottawa (CA)

(21) Appl. No.: 19/288,200

(22) Filed: Aug. 1, 2025

Related U.S. Application Data
(60) Provisional application No. 63/678,874, filed on Aug. 2, 2024.

(51) Int. Cl. G06F 30/27; G06F 30/28

(52) U.S. Cl. CPC G06F 30/27; G06F 30/28

(57) ABSTRACT

Systems and methods relating to identifying raw materials and predicting gas production based on the identified raw materials. Machine learning models are used to identify (through pattern matching or curve fitting) raw materials. Once the raw materials are identified, expected gases and their quantities produced through fermentation are determined using another machine learning model. The predicted gases and amounts are then sent to a user.

### RELATED APPLICATIONS

This application claims priority to and the benefit of U.S. Provisional Patent Application 63/678,874, filed Aug. 2, 2024.

### TECHNICAL FIELD

The present invention relates to specific animal feeds and which gases are produced during fermentation of such animal feeds, manure, and soil samples. More specifically, the present invention relates to systems and methods for determining, based on scanning such samples which gases and what amounts are produced by such fermentation.

### BACKGROUND

The identification of a climate change emergency in the 2010s has led to an increased focus on and increased concern about greenhouse gases and its sources. One well-known source of greenhouse gases is enteric greenhouse gas production in livestock. More specifically, such greenhouse gas production can be focused on the production of such gases by bovine livestock. According to some sources, cattle are the largest source of agricultural methane. Such sources detail that cattle contribute approximately 89% of emissions.

Research in this field shows that the amount of and type of gases produced by cattle is greatly affected or caused by the type of animal feed provided to the cattle. However, determining the raw materials used for cattle feed and then determining what gases are produced by the digestion/fermentation of such raw materials by cattle is not only quite difficult but is also time consuming. This process may involve, once a sample of the feed has been obtained, analyzing that feed and then performing studies on how the feed material breaks down in the presence of cattle stomach/rumen chemicals.

Another well-known source of greenhouse gases is soil. Nitrous oxide can result from field-applied fertilizers, crop residue decomposition and manure storage. Similarly, carbon dioxide emissions can come from plant decomposition, soil amendments, and fertilizers. As is well-known, carbon dioxide is released from soil when soil organic matter breaks down. Therefore, determining the soil composition from a specific area can assist in determining how much greenhouse gases (and non-greenhouse gases) can result/be emitted from that area. Unfortunately, much like cattle feed, determining soil composition and predicting gas produced by such a soil decomposition is a laborious and prolonged process.

There is therefore a need for a simpler and quicker process to determine what, if any gases may be produced when specific raw materials are ingested by cattle and, similarly, what gases may be produced by specific soil samples once the soil decomposes.

### SUMMARY

The present invention provides systems and methods relating to identifying raw materials and predicting gas production based on the identified raw materials as well as the associative effects of the processing of such raw materials. Machine learning models are used to identify (through pattern matching or curve fitting) raw materials. Once the raw materials are identified, expected gases and their quantities produced through fermentation are determined using another machine learning model. The predicted gases and amounts are then sent to a user.

In a first aspect, the present invention provides a method for determining resulting gases from fermentation of raw materials, the method comprising:
a) scanning said raw materials to determine raw material spectra for said raw materials;
b) uploading said raw material spectra to a server for analysis;
c) determining which matching spectra in a database of spectra for known raw materials matches said raw material spectra;
d) based on results of step c), determining predicted gas production characteristics of said raw materials if said raw materials were naturally fermented;
e) providing said predicted gas production characteristics to a user.

In a second aspect, the present invention provides a system for determining resulting gases from fermentation of raw materials, the system comprising:
a first trained machine learning model for matching a spectra of an unknown raw material with a spectra of a known raw material;
a second trained machine learning model for predicting gas production data for said unknown raw material based on gas production data of said known raw material;
a database containing spectra of known raw materials and gas production data for said known raw materials;
   wherein
said first trained machine learning model is trained using a training dataset that includes said spectra of known raw materials;
said second trained machine learning model is trained using a trained dataset that includes said gas production data for said known raw materials.

In a third aspect, the present invention provides a system for measuring gases from raw materials after natural fermentation, the system comprising:
a material identification module for identifying an unknown raw material based on a spectra of said unknown material;
a gas production module for determining gas production data for said unknown raw material based on an identification of unknown raw material;
a database containing spectra of known raw materials and gas production data for known raw materials;
   wherein
said material identification module identifies said unknown raw material based on said spectra of said unknown raw material and said spectra of known raw materials;
said gas production module determines said gas production data for said unknown raw material based on gas production data of said known raw materials and on said identification of said unknown raw material.

In one aspect, data relating to resulting gas production is determined by processing raw materials in a simulated rumen and measuring by-products resulting from the processing of raw materials.

In another aspect, data relating to resulting gas production is determined by processing raw materials in a vessel wherein heat is applied to the raw materials and measuring by-products resulting from the processing of raw materials.

In a further aspect, the raw materials include at least one of: animal feed, manure, and soil.

In yet another aspect, the material identification module performs at least one of: curve fitting and pattern matching to determine a matching spectra to the spectra of the unknown raw material.

In a further aspect, the gas production module and/or the second trained machine learning model predicts gas production data for the unknown raw material based on an extrapolation of the gas production data of the known raw materials.

### BRIEF DESCRIPTION OF THE DRAWINGS

The embodiments of the present invention will now be described by reference to the following figures, in which identical reference numerals in different figures indicate identical elements and in which:

FIG. 1 is a schematic diagram illustrating one aspect of the present invention;

FIG. 2 is a block diagram of a system according to one aspect of the present invention; and

FIG. 3 is a flowchart detailing the steps in a method according to another aspect of the present invention.

### DETAILED DESCRIPTION

As noted above, the present invention involves obtaining the spectra of a sample of raw material. The raw material may be a soil sample, a manure sample, or may be a sample of feed for use in feeding cattle or other farm animals. The term “raw material” includes blended or composite raw materials and includes samples that are mixes. The spectra of the raw material is obtained by way of a suitable scanner and is then uploaded to a processing server. The processing server then processes the spectra to determine if the spectra matches the spectra of a known raw material or a raw material for which gas data is known or can be predicted. When the matching spectra has been determined, the gas data for the raw material is then retrieved or predicted. The predicted or retrieved gas data is then sent to the user. The gas data may be provided to the user by way of a suitable computing device.

Also as noted above, the matching of the raw material spectra may be performed by a trained machine learning model. Similarly, the prediction of the gas data may also be performed using another trained machine learning model.

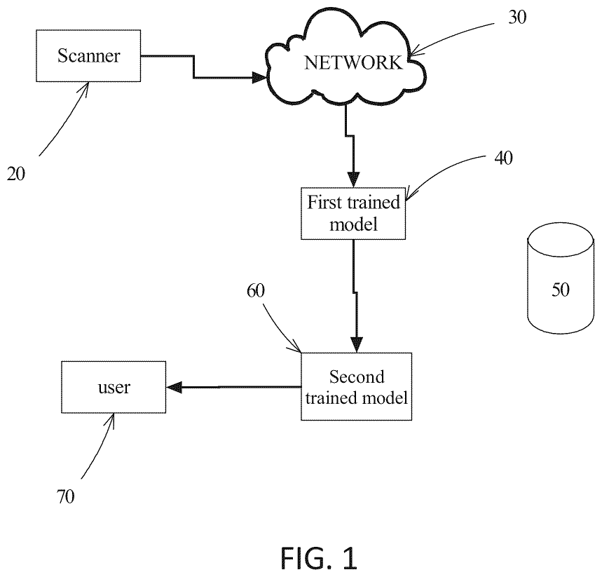

Referring to FIG. 1, the process 10 of one aspect of the present invention is schematically illustrated. The unknown raw material is first obtained and then scanned for its spectra using, in one aspect, a handheld scanner 20. The spectra resulting from the scanning is transmitted to a cloud-based application through a network 30 and is received by a first trained machine learning model 40. The first trained machine learning model 40 determines the raw material (or its suitable analogue) by way of pattern matching or curve-fitting to determine which raw material spectra in its database 50 best fits the spectra from the raw material.

Once the best matching spectra of known (or previously encountered) raw materials has been determined, the result is then sent to a second trained machine learning model 60. This second trained machine learning model 60 has access to the gas production data for the raw material with the best matching spectra and, based on this gas production data, then extrapolates the predicted gas production data for the unknown raw material. This predicted gas production data is then sent to the user.

For clarity, the first trained machine model 40 performs pattern matching or curve matching to determine the unknown raw material's feed type, how this feed is digested by cattle, and, accordingly, the types of greenhouse gases and non-greenhouse gases produced by the digestion. For manure and soil samples, the first trained machine model 40 determines the type of raw material as well as its other characteristics that would be indicative of its fermentation characteristics/outcome.

Once the first trained machine model 40 has determined the unknown raw material (and its characteristics as noted above including feed type, digestion characteristics, and greenhouse and non-greenhouse gases produced), this raw material identification data is passed to the second trained machine model 60. The second trained machine model 60 then takes this identification data and, based on the identification data and tested data in the database 50, extrapolates gas production data. For clarity, the database 70 contains not just identification data but experimental data detailing raw materials, the gases it has produced, and the amount of such gases produced. These data points are then used as the basis for the extrapolated predicted gas production data.

For clarity, the gases that may be produced include methane, carbon dioxide, hydrogen, ammonia, and nitrous oxide. The characteristics of the output (as part of the gas production data) may include the resulting pH, ORP (oxidation-reduction potential) and pressure (psi) of the resulting output once the raw material has been fermented. The present invention may be used with methane (CH₄), carbon dioxide (CO₂), hydrogen (H₂), ammonia (NH₃), and nitrous oxide (N₂O) in samples.

Again for clarity, the first trained machine model performs pattern and/or curve matching using the unknown raw material's spectra to pattern/curve match with the spectra of known/previously encountered raw materials. The best match to the unknown raw material's spectra is the used to gather the raw material identification data for the best matching raw material. Once the raw material identification data is gathered (including feed type, cattle digestion/fermentation characteristics, gases produced (both greenhouse and non-greenhouse)), both the unknown raw material's spectra and the raw material identification data are used by the second trained machine model to extrapolate the predicted gas production data for the unknown raw material. Since the raw material identification data already predicts the expected gases, the digestion/fermentation characteristics and the amounts of gases produced by the best matching raw materials can be used by the second trained machine model to predict the amount of each gas from the unknown raw materials. The predicted gas production data, once produced, can then be sent to the user.

It should be clear that the spectra that may be used by the present invention may be spectra derived from using Near-infrared (NIR) spectroscopy. Portable/handheld NIR scanners (as well as benchtop NIR scanners) are well-known in the agricultural industries and can be used with the present invention. Other spectra, such as that obtained using UV, visible, or mid-infrared (MIR) scanners, may also be used.

In terms of the data used for the database, this can be obtained and stored by simulating cattle digestion. For such data, a suitable vessel/container can be used as a simulated cattle (e.g. cow) rumen and can contain suitable cattle rumen contents such as that obtained from a real cow or from a slaughtered cow. Suitable raw material can then be introduced into vessel and be “digested” (i.e. fermented) by the contents and the resulting gases/by products can be measured/analyzed. The measurements and/or analysis can then form part of the basis for one or more data sets for the database for that raw material which was “digested” (or fermented) by the simulated cattle rumen. The spectra for that raw material can, of course, be obtained by scanning the raw material and the resulting spectra can be stored in the database and associated with the digestion results.

As should be clear, many experiments and many “digestions” or fermentations using simulated cattle rumens may be necessary to arrive at a suitable database.

For manure and/or soil samples, data for the database can be generated by simulation of natural fermentation (i.e. fermentation in outdoor air). For such data, a suitable vessel is obtained and a sample of the raw material is introduced into the vessel. The vessel can then be sealed and heat is applied to the vessel to simulate natural heat and/or time and the resulting output (including gases and their characteristics) can then be measured and/or analyzed. As with animal feed, multiple experiments or fermentations may need to be performed with various types of manure and/or soils to build a suitable database for use with the present invention.

Once the database has been populated, the various data points and data sets in the database can then be used to train the first and second trained machine learning models. The spectra from the known/encountered raw materials can form at least part of the training data set for the curve fitting/pattern matching first trained machine learning model. Similarly, the digestion characteristics and the gas produced by the digested known/encountered raw materials can be used as part of the training dataset for the second trained machine learning model. For clarity, the training dataset for the second trained machine learning model can include multiple data points/gas production data points for the same or similar raw materials or for raw materials with similar spectra. This would allow the second trained machine learning model to extrapolate based on the data in the database. As an example, if the data in the training data set details that, for raw material A with quantity B of raw material component C and quantity D of raw material component E, gas Q of quantity Q1 and gas R of quantity R1 is produced. Similarly, the training data set could include the data point where, for raw material A with quantity B1 of raw material component C and quantity D1 of raw material component E, gas Q of quantity Q2 and gas R of quantity R2 is produced. Thus, if a matching raw material A1 with with quantity B3 of raw material component C and quantity D3 of raw material component E is provided, the second trained machine learning model may extrapolate that this raw material A1 would produce gas Q of quantity Q3 and gas R of quantity R3.

As can be imagined, the quality and the quantity of the data in the databases and the amount of training and the extent of the training datasets for the machine learning models can have a significant effect on the performance of the machine learning models. This can also significantly affect the accuracy and precision of the results from the different trained machine learning models.

In some implementations, the database may include measurements for pH and ORP (Oxidation Reduction Potential) for the by-products of the “digestion” from the simulated cattle stomach. As is known, ORP measures a substance's ability to oxidize or reduce another substance in a solution. In simpler terms, ORP is a way to quantify a solution's electron transfer capability. Measurements for the pH and ORP may be taken, along with gas measurements, once the digestion or processing or fermentation of the raw material has taken place within the simulated cattle/cow rumen. Measurements for the pH and ORP may also be taken for manure and soil samples once these have been fermented by the simulation noted above using heat.

For greater clarity, the results produced by the two trained machine learning models may be placed into the database and may form part of a subsequent training data set for the machine learning models. Preferably, every time a new raw material or a new combination of raw materials is processed by the system, the machine learning models are retrained to incorporate the results produced. Similarly, every time new data points are obtained (either through lab experiments or lab based simulations of cattle digestion using different or known raw materials), these data points are incorporated into the machine learning models by retraining the models with training data sets that incorporate these data points.

Regarding the possible implementations of the various aspects of the present invention, the scanner to obtain the spectra of the unknown raw material may by a handheld or portable scanner. Such a scanner may be a non-portable, desk or laboratory-based scanner. As noted above, the spectra obtained by the scanner may be one of multiple possible spectra obtained using NIR, visual, IR, UV, or other types of spectroscopy.

Once the spectra has been obtained, this spectra can then be uploaded to a server for processing. The uploading may be performed using a suitable device such as a suitably configured mobile computing device such as a smartphone or similarly equipped or similarly capable device. The device may be equipped with a suitable app, application, or software that allows the device to interact/couple with the scanner to receive the scanned spectra. The spectra can then be uploaded by the device to a network (e.g. the Internet) to be received by a server for processing.

Regarding the server that receives and processes the spectra, this may be embodied in a suitable cloud computing platform that provides both the processing power and the storage requirements for the various aspects of the present invention. As can be imagined, for a large database (or a data lake in some embodiments), a cloud storage implementation may be best suited. Similarly, for the machine learning models, the processing power that may be used in both the training and in the processing of the spectra as well as the gas production prediction can be obtained using a cloud computing platform. The cloud computing platform provides the suitable processing power as well as the speed and storage size that may be needed for a large database/datalake. Of course, other implementations may be possible. As an example, a portable scanner that is dedicated to scanning the unknown raw material, transmitting the scanned spectra by way of a network, and receiving the predicted gas production data (e.g. the expected gases as well as indications as to the quantity of each predicted gas) can be used. Similarly, the scanning can be performed by one suitable device while the reception of the scanned spectra, the communicating with the server, and the receiving of the predicted gas production data can be performed by another device.

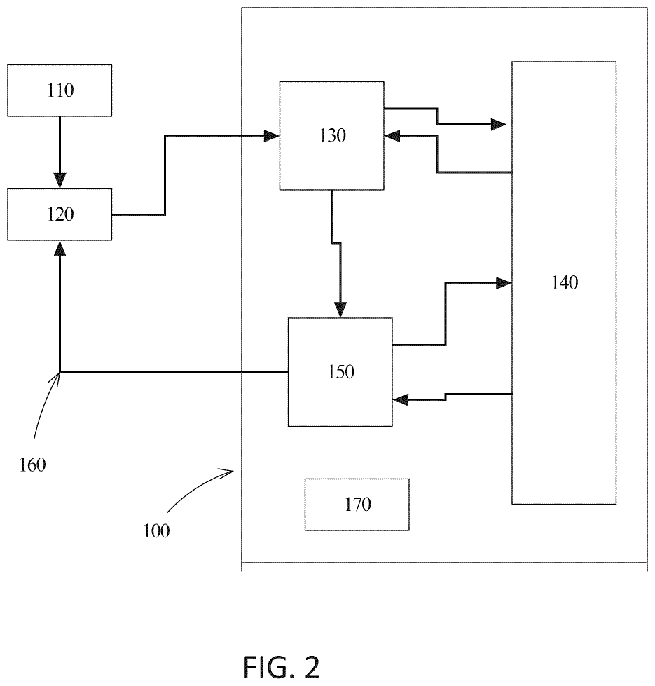

Referring to FIG. 2, illustrated is a block diagram detailing the components in a system 100 according to one aspect of the present invention As can be seen, the system 100 involves a scanner 110 that scans the raw material and sends the resulting spectra to a mobile device 120. As noted above, the mobile device may be a smartphone or similarly capable device that can send the resulting spectra to the system 100. This can, of course, be performed by way of uploading the spectra of the unknown raw material through the Internet to the server that embodies the system 100.

Referring to the system 100, a material identification module 130 receives the spectra of the unknown raw material. The material identification module, which may be a first trained machine learning model, performs pattern matching and/or curve fitting to identify the known raw material with the closest spectra to the spectra received from the mobile device. Of course, a 100% identical match between the spectra is not necessary for a match. In some implementations, a match for even a portion of the spectra is sufficient as long as the first trained machine learning model has sufficient confidence that the match is correct. As can be seen in FIG. 2, the material identification module 130 can retrieve data from the database 140. This data can be the raw material identification data (including feed type, cattle digestion/fermentation characteristics, gases produced (both greenhouse and non-greenhouse)) for the identified raw material. Similarly, the data retrieved from the database can be spectra to be matched to the spectra of the unknown raw material. Regardless of the data retrieved, the material identification module 130 passes the matching raw material and/or the raw material identification data to the gas production data module 150.

The gas production module 150, once it has received data relating to the identification of the matching raw material, can either retrieve the raw material identification data for that matching raw material (if this has not yet been retrieved) or proceed to predict gas production data based on the already received raw material identification data. It should be clear that a second trained machine learning model can embody the gas production module and that this component predicts the gas production data for the unknown raw material including gases produced after digestion/fermentation and the amounts of each gas predicted to be produced. Based on the data that the gas production module 150 receives (from one or both of the material identification module 130 and the database 140), the gases are predicted as well as the amount of each gas. This gas production data 160 is then transmitted back to the mobile device 120 as necessary by way of a communications module 170. For clarity, other communications with the server 100 can also be routed through the communications module 170.

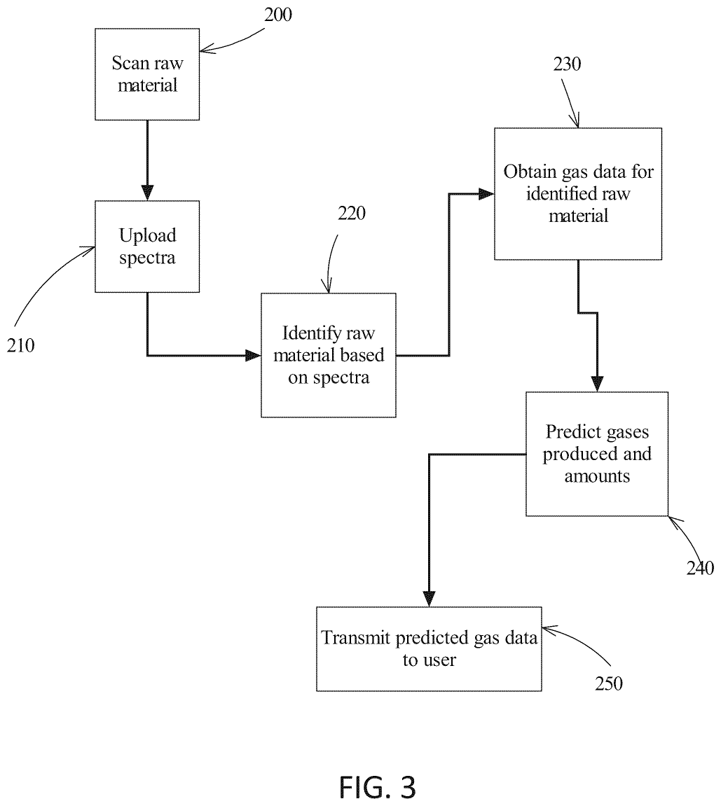

Referring to FIG. 3, illustrated is a flowchart detailing the steps in a method according to another aspect of the present invention. As can be seen, the method starts with step 200, that of scanning the unknown raw material for its spectra. The resulting spectra is then uploaded to a server in step 210. The server then processes the spectra in step 220 as the raw material is identified based on its spectra. As noted above, this can be performed using a first trained machine learning model. Once the matching spectra has been determined, step 230 is that of retrieving the raw material identification data from the database based on the matching spectra. In step 204, the gases produced by the unknown raw material and the amounts to be produced are predicted based on the raw material identification data retrieved in step 230. After the gas data has been predicted, this gas data is then transmitted to the user in step 250.

Some example embodiments are described above with reference to the accompanying drawings, in which some, but not all example embodiments are shown. The examples described and pictured herein should not be construed as being limiting as to the scope, applicability or configuration of the present disclosure. It should be noted that like reference numerals refer to like elements throughout. Furthermore, as used herein, the term “or” is to be interpreted as a logical operator that results in true whenever one or more of its operands are true. As used herein, operable coupling should be understood to relate to direct or indirect connection that, in either case, enables functional interconnection of components that are operably coupled to each other. Additionally, when the term “data” is used, it should be appreciated that the data may in some cases include simply data or a particular type of data generated based on operation of algorithms and computational services, or, in some cases, the data may actually provide computations, results, algorithms and/or the like that are provided as services.

As used in herein, the term “module” is intended to include a computer-related entity, such as but not limited to hardware, firmware, or a combination of hardware and software (i.e., hardware being configured in a particular way by software being executed thereon). For example, a module may be, but is not limited to being, a process running on a processor, a processor (or processors), an object, an executable, a thread of execution, and/or a computer. By way of example, both an application running on a computing device and/or the computing device can be a module. One or more modules can reside within a process and/or thread of execution and a module may be localized on one computer and/or distributed between two or more computers. In addition, these components can execute from various computer readable media having various data structures stored thereon. The modules may communicate by way of local and/or remote processes such as in accordance with a signal having one or more data packets, such as data from one module interacting with another module in a local system, distributed system, and/or across a network such as the Internet with other systems by way of the signal. Each respective module may perform one or more functions that will be described in greater detail herein. However, it should be appreciated that although this example is described in terms of separate modules corresponding to various functions performed, some examples may not necessarily utilize modular architectures for employment of the respective different functions. Thus, for example, code may be shared between different modules, or the processing circuitry itself may be configured to perform all of the functions described as being associated with the modules described herein. Furthermore, in the context of this disclosure, the term “module” is to be understood to be a modular component that is specifically configured in, or can be operably coupled to, the processing circuitry to modify the behavior and/or capability of the processing circuitry based on the hardware and/or software that is added to or otherwise operably coupled to the processing circuitry to configure the processing circuitry accordingly.

It should be clear that the various aspects of the present invention may be implemented as software modules in an overall software system. As such, the present invention may thus take the form of computer executable instructions that, when executed, implements various software modules with predefined functions.

Additionally, it should be clear that, unless otherwise specified, any references herein to ‘image’ or to ‘images’ refer to a digital image or to digital images, comprising pixels or picture cells. Likewise, any references to an ‘audio file’ or to ‘audio files’ refer to digital audio files, unless otherwise specified. ‘Video’, ‘video files’, ‘data objects’, ‘data files’ and all other such terms should be taken to mean digital files and/or data objects, unless otherwise specified.

The embodiments of the invention may be executed by a computer processor or similar device programmed in the manner of method steps, or may be executed by an electronic system which is provided with means for executing these steps. Similarly, an electronic memory means such as computer diskettes, CD-ROMs, Random Access Memory (RAM), Read Only Memory (ROM) or similar computer software storage media known in the art, may be programmed to execute such method steps. As well, electronic signals representing these method steps may also be transmitted via a communication network.

Embodiments of the invention may be implemented in any conventional computer programming language. For example, preferred embodiments may be implemented in a procedural programming language (e.g., “C” or “Go”) or an object-oriented language (e.g., “C++”, “java”, “PHP”, “PYTHON” or “C#”). Alternative embodiments of the invention may be implemented as pre-programmed hardware elements, other related components, or as a combination of hardware and software components.

Embodiments can be implemented as a computer program product for use with a computer system. Such implementations may include a series of computer instructions fixed either on a tangible medium, such as a computer readable medium (e.g., a diskette, CD-ROM, ROM, or fixed disk) or transmittable to a computer system, via a modem or other interface device, such as a communications adapter connected to a network over a medium. The medium may be either a tangible medium (e.g., optical or electrical communications lines) or a medium implemented with wireless techniques (e.g., microwave, infrared or other transmission techniques). The series of computer instructions embodies all or part of the functionality previously described herein. Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies. It is expected that such a computer program product may be distributed as a removable medium with accompanying printed or electronic documentation (e.g., shrink-wrapped software), preloaded with a computer system (e.g., on system ROM or fixed disk), or distributed from a server over a network (e.g., the Internet or World Wide Web). Of course, some embodiments of the invention may be implemented as a combination of both software (e.g., a computer program product) and hardware. Still other embodiments of the invention may be implemented as entirely hardware, or entirely software (e.g., a computer program product).

A person understanding this invention may now conceive of alternative structures and embodiments or variations of the above all of which are intended to fall within the scope of the invention as defined in the claims that follow.

We claim:

1. A method for determining resulting gases from fermentation of raw materials, the method comprising:
a) scanning said raw materials to determine raw material spectra for said raw materials;
b) uploading said raw material spectra to a server for analysis;
c) determining which matching spectra in a database of spectra for known raw materials matches said raw material spectra;
d) based on results of step c), determining predicted gas production characteristics of said raw materials if said raw materials were naturally fermented;
e) providing said predicted gas production characteristics to a user.

2. The method according to claim 1, wherein step c) is executed using a first machine learning model.

3. The method according to claim 2, further comprising training said first machine learning model using spectra in said database.

4. The method according to claim 1, wherein step d) is executed using a second machine learning model.

5. The method according to claim 4, further comprising training said second machine learning model using data relating to gas production from different raw materials, said data being stored in said database.

6. The method according to claim 5, wherein said data relating to resulting gas production is determined by processing raw materials in a simulated rumen and measuring by-products resulting from said processing of raw materials.

7. The method according to claim 1, wherein step a) is executed using a portable scanner.

8. The method according to claim 1, wherein step b) is executed using a mobile communications device, said mobile communications device receiving said spectra after step a) is executed.

9. The method according to claim 1, wherein step d) is determined based on if said raw materials were ingested by an animal.

10. The method according to claim 1, wherein step d) is determined based on if said raw materials were fermented by way of applying heat.

11. The method according to claim 5, wherein said data relating to resulting gas production is determined by processing raw materials in a vessel wherein heat is applied to said raw materials and measuring by-products resulting from said processing of raw materials.

12. The method according to claim 1, wherein said raw materials include at least one of: animal feed, manure, and soil.

13. The method according to claim 1, wherein providing said predicted gas production characteristics are for gases that include at least one of: methane (CH₄), carbon dioxide (CO₂), hydrogen (H₂), ammonia (NH₃), and nitrous oxide (N₂O).

14. A system for determining resulting gases from fermentation of raw materials, the system comprising:
a first trained machine learning model for matching a spectra of an unknown raw material with a spectra of a known raw material;
a second trained machine learning model for predicting gas production data for said unknown raw material based on gas production data of said known raw material;
a database containing spectra of known raw materials and gas production data for said known raw materials;
wherein
said first trained machine learning model is trained using a training dataset that includes said spectra of known raw materials;
said second trained machine learning model is trained using a trained dataset that includes said gas production data for said known raw materials.

15. The system according to claim 14, further comprising a communications module for receiving said spectra of said unknown raw material.

16. The system according to claim 15, wherein predicted gas production data is transmitted by said communications module to a user.

17. The system according to claim 14, wherein at least a portion of said gas production data in said database is derived from processing raw materials in a simulated animal rumen and measuring by-products resulting from said processing of raw materials.

18. The method according to claim 15, wherein at least a portion of said gas production data in said database is derived from processing raw materials in a vessel and wherein heat is applied to said raw materials and measuring by-products resulting from said processing of raw materials.

19. The system according to claim 14, wherein said system receives said spectra of said unknown raw material from a scanner external to said system.

20. The system according to claim 14, wherein said system is implemented using a cloud computing platform.

21. The system according to claim 14, wherein said first and second trained machine learning models are trained whenever there is new data in said database.
